(19) United States
(12) Patent Application Publication
(10) Pub. No.: US 2016/0075920 A1
(43) Pub. Date: Mar. 17, 2016

(54) ADHESIVE FILM FOR SEMICONDUCTOR DEVICE

(71) Applicant: SAMSUNG SDI CO., LTD., Yongin-si (KR)

(72) Inventors: Dong Seon UH, Suwon-si (KR); Gyu Seok SONG, Suwon-si (KR); Min Kyu HWANG, Suwon-si (KR); Ki Tae SONG, Suwon-si (KR); Dae Ho SEO, Suwon-si (KR)

(21) Appl. No.: 14/950,366

(22) Filed: Nov. 24, 2015

Related U.S. Application Data
(63) Continuation of application No. 13/272,550, filed on Oct. 13, 2011.

(30) Foreign Application Priority Data
Dec. 6, 2010 (KR) 10-2010-0123810

(51) Int. Cl. C09J 7/02; H01L 23/00; H01L 21/683; B32B 7/06; B32B 27/08

(52) U.S. Cl. CPC C09J 7/0217; B32B 7/06; B32B 27/08; H01L 21/6836; H01L 24/29; B32B 2405/00; B32B 2255/10; B32B 2255/26; B32B 2255/28; B32B 2307/30; H01L 2221/68327; H01L 2221/68318; H01L 2224/2919; H01L 2224/2929; H01L 2924/0635; H01L 2924/0665; H01L 2924/07025; H01L 2924/068; H01L 2924/061; H01L 2924/0615; H01L 2924/0705; H01L 2924/0675; H01L 2224/29084

(57) ABSTRACT

An adhesive film for semiconductor devices, the adhesive film including a base film having a coefficient of linear expansion of about 50 to about 150 μm/m•° C. at 0 to 5° C.

### CROSS-REFERENCE TO RELATED APPLICATION

This application is a continuation of U.S. patent application Ser. No. 13/272,550, filed Oct. 13, 2011, and entitled “ADHESIVE FILM FOR SEMICONDUCTOR DEVICE,” the entire contents of which are hereby incorporated by reference.

### BACKGROUND

1. Field

Embodiments relate to an adhesive film for semiconductor devices.

2. Description of the Related Art

Silver pastes may be used to bond semiconductor devices together or to bond a semiconductor device to a supporting member. As semiconductor devices become smaller and capacity increases, supporting members for semiconductor devices may also be smaller and more precise.

Silver paste may leak or may cause inclination of a semiconductor device. As a result, malfunctions may occur, bubbles may be generated, and/or thickness control during wire bonding may be difficult to achieve. Accordingly, a bonding film may be used as an alternative to silver paste.

### SUMMARY

Embodiments are directed to an adhesive film for semiconductor devices.

The embodiments may be realized by providing an adhesive film for semiconductor devices, the adhesive film comprising a base film having a coefficient of linear expansion of about 50 to about 150 μm/m•° C. at 0 to 5° C.

The base film may have a thermal contraction ratio of greater than 0 to about 0.1% after 120 hours at 5° C.

The base film may include at least one of a polyolefin, polyethylene terephthalate, polycarbonate, poly(methyl methacrylate), polyimide, polyethylene naphthalate, polyester sulfone, polystyrene, a polyacrylate, and a thermoplastic elastomer.

The base film may include the polyolefin, the polyolefin including one of polyethylene, polypropylene, ethylene/propylene copolymer, polybutylene-1, ethylene/vinyl acetate copolymer, polyethylene/styrene butadiene rubber mixture, and polyvinyl chloride.

The base film may include the thermoplastic elastomer, the thermoplastic elastomer including one of polyurethane and a polyamide-polyol copolymer.

The adhesive film may further include a pressure sensitive adhesive layer on one side of the base film.

The pressure sensitive adhesive layer may include a pressure sensitive adhesive binder, a heat curing agent, and a photoinitiator.

The pressure sensitive adhesive binder may have a weight average molecular weight of about 100,000 to about 1,000,000.

The adhesive film may further include a bonding layer and a protective film sequentially stacked on one side of the pressure sensitive adhesive layer.

The adhesive film may have a thermal contraction ratio of greater than 0 to about 0.2% after 120 hours at 5° C.

The bonding layer may include an acrylic resin and an epoxy resin.

The acrylic resin may have a glass transition temperature of about −30° C. to about 10° C., and the epoxy resin may include one of a bisphenol-A resin, a phenol novolac resin, and a cresol novolac resin.

### BRIEF DESCRIPTION OF THE DRAWINGS

The embodiments will become apparent to those of ordinary skill in the art by describing in detail exemplary embodiments with reference to the attached drawings, in which:

FIG. 1 illustrates a perspective view showing tilting of a base film due to thermal contraction;

FIG. 2 illustrates a cross-sectional view showing the concept of thermal contraction ratio;

FIG. 3 illustrates a cross-sectional view of an adhesive film for semiconductor devices according to an embodiment;

FIG. 4 illustrates a sectional view of an adhesive film, showing an evaluation method of winding shape stability;

FIG. 5 illustrates a side view of the adhesive film in a direction of Arrow A in FIG. 4; and

FIG. 6 illustrates a side view of the adhesive film seen in a direction of Arrow B in FIG. 4.

### DETAILED DESCRIPTION

Korean Patent Application No. 10-2010-0123810, filed on Dec. 6, 2010 in the Korean Intellectual Property Office, and entitled: “Adhesive Film for Semiconductor Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The embodiments provide an adhesive film (including a base film) for a semiconductor manufacturing process, which may have excellent low-temperature storage characteristics. The base film may have a coefficient of linear expansion of about 50 to about 150 μm/m•° C. at 0 to 5° C., e.g., about 50 to about 120 μm/m•° C. or about 60 to about 100 μm/m•° C. The base film may have a thermal contraction ratio of greater than 0 to about 0.1% after 120 hours at 5° C., e.g., greater than 0 to about 0.06%.

Maintaining the thermal contraction ratio and the coefficient of linear expansion within the above range may help ensure that the base film has excellent low-temperature storage characteristics and desirable properties for a semiconductor packaging process, e.g., an expanding process, even when the base film is wound with low tension.

The base film may have a single-layer structure or a multi-layer structure of at least two layers. In an implementation, the base film may be formed of a material transparent to visible light, UV light, or the like. In another implementation, the base film may be formed of an opaque material.

The base film may be selected depending on use and conditions thereof. For example, the base film may include at least one of a polyolefin film (e.g., polyethylene (PE), polypropylene (PP), ethylene/propylene copolymer, polybutylene-1, ethylene/vinyl acetate copolymer, polyethylene/styrene-butadiene rubber mixture, or the like), polyvinylchloride (PVC), polyethylene terephthalate (PET), polycarbonate, poly(methyl methacrylate), polyimide (PI), polyethylene naphthalate (PEN), polyester sulfone, polystyrene (PS), polyacrylate (PAR), and thermoplastic elastomers, (e.g., polyurethane, a polyamide-polyol copolymer, or the like), without being limited thereto.

FIG. 1 illustrates a perspective view of tilting of a base film due to thermal contraction.

Referring to FIG. 1, a base film 104 or bonding tape (adhesive film) for semiconductor assembly may be wound around a reel 102 at a low temperature (e.g., about 5° C. or less) and stored at low temperature for a long time before use. However, consideration should be given to possible vulnerability of the base film 104 to heat at low temperature, and thermal contraction and voids generated in the base film, e.g., between the rolled layers, when the base film is stored at low temperature for a long time. Such may result in tilting of the bonding tape in one direction during movement and operation thereof. For example, as shown in FIG. 1, the base film or the bonding tape 104 for semiconductor assembly (wound around the reel 102) could move side to side (in an arrow direction), so that a circular wafer may not be attached at a proper position upon mounting of a pre-cut type.

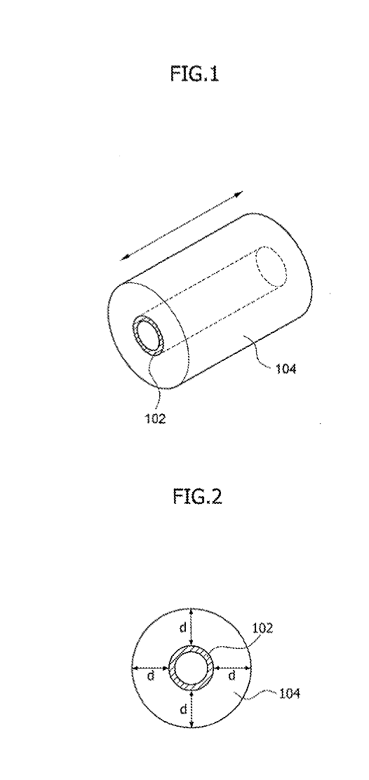

FIG. 2 illustrates a cross-sectional view showing the concept of thermal contraction ratio.

Referring to FIG. 2, the thermal contraction ratio of a base film may be defined using a contraction rate in a direction vertical or orthogonal to an axis on which the base film is wound into a roll. For example, after the base film 104 (wound around a reel 102) is left at low temperature for a long time, a variation in length (d) in the direction orthogonal to the axis may be measured to thereby define the thermal contraction ratio.

The coefficient of linear expansion of the base film may be defined as a coefficient of thermal expansion measured while elevating a temperature at 5° C./min from −20° C. to 300° C.

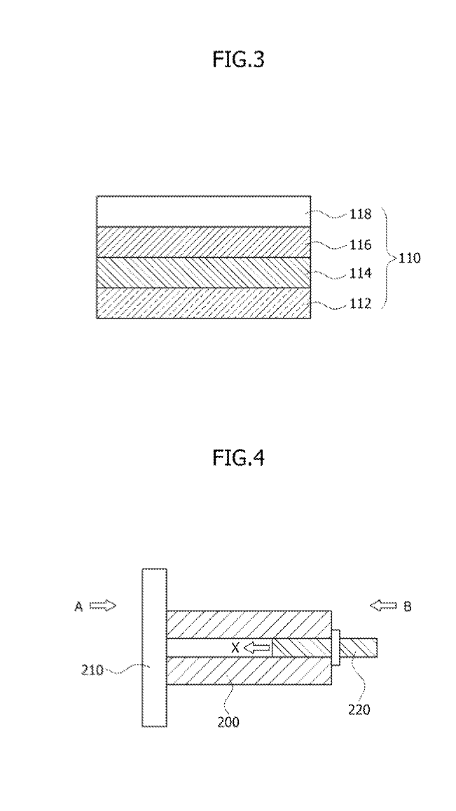

FIG. 3 illustrates a cross-sectional view of an adhesive film for semiconductor devices according to an embodiment. Herein, an “adhesive film” may refer to a tape or film that has at least one of a pressure sensitive adhesive function or a bonding function.

Referring to FIG. 3, the adhesive film 110 for a semiconductor device according to the present embodiment may include a base film 112, a pressure sensitive adhesive layer 114, a bonding layer 116, and a protective film 118. Although the adhesive film 110 is illustrated as including both the bonding layer 116 and the protective film 118 in FIG. 3, both the bonding layer 116 and the protective film 118 may be omitted or the bonding layer 116 alone may be omitted, as desired. For example, when used as a dicing tape, the adhesive film 110 may include only the base film 112 and the pressure sensitive adhesive layer 114.

According to an embodiment, the adhesive film 110 for semiconductor devices may have a four-layer structure (including the base film 112, the pressure sensitive adhesive layer 114, the bonding layer 116, and the protection layer 118) and may have a thermal contraction ratio of greater than 0 to about 0.2% after 120 hours at 5° C., e.g., greater than 0 to about 0.1% or greater than 0 to about 0.08%. Within this range, the adhesive film 110 may exhibit excellent low-temperature storage and expansion properties, and occurrence of a tilting phenomenon during low-temperature storage may be reduced or prevented, even if the adhesive film 110 is wound with low tension.

Components and properties of the adhesive film according to the present embodiment will now be described in more detail.

(1) Base Film

The base film 112 of the adhesive film 110 for semiconductor devices may have a coefficient of linear expansion of about 50 to about 150 μm/m•° C. at 0 to 5° C., e.g., about 50 to about 120 μm/m•° C. or about 60 to about 100 μm/m•° C. The base film 112 may have a thermal contraction ratio of greater than 0 to about 0.1% after 120 hours at 5° C., e.g., greater than 0 to about 0.06%. In an implementation, the base film 112 may be suitable for back-grinding and dicing processes.

Various kinds of plastic films may be used as the base film 112 for the back-grinding process. For example, an expandable thermoplastic film may be used as the base film 112. A wafer having a circuit pattern may be susceptible to damage or breakage due to generation of cracks upon exposure to physical impact during back grinding. Therefore, the expandable thermoplastic film may be used as the base film 112 to protect the wafer from impact during the back-grinding process through absorption and relief of impact.

The base film 112 may be expandable and may also be transparent to UV light. For example, when the pressure sensitive adhesive layer 114 includes a UV curable adhesive composition, it may be desirable for the base film 112 to exhibit excellent transparency to UV light at a frequency at which the adhesive composition is cured. Thus, in this case, the base film 112 may not contain a UV light absorbent.

It may be desirable for the base film 112 to be chemically stable. For example, although the base film 112 may be prepared in consideration of heavy impact applied during the back-grinding process, it may be desirable for the base film 112 to exhibit chemical stability because a final polishing stage may be performed using a chemical mechanical polishing (CMP) slurry. In an implementation, polymeric compounds, e.g., polyolefins, which are chemically stable, may be suitably used for the base film 112. However, the embodiments are not limited thereto, and other materials may also be used.

Examples of the base film 112 may include at least one of polyolefin films (such as polyethylene (PE), polypropylene (PP), ethylene/propylene copolymer, polybutylene-1, ethylene/vinyl acetate copolymer, polyethylene/styrene-butadiene rubber mixture, polyvinylchloride films, and the like), polyethylene terephthalate (PET), polycarbonate, poly(methyl methacrylate), polyimide (PI), polyethylene naphthalate (PEN), polyester sulfone, polystyrene (PS), polyacrylate (PAR), and thermoplastic elastomers (such as polyurethane, a polyamide-polyol copolymer, and the like), without being limited thereto.

The base film 112 may be formed by an extrusion process after blending and melting chips of these materials. Alternatively, the base film may be formed by blowing. Thermal resistance and mechanical properties of the base film 112 may be determined depending on the kind of chips blended.

The base film 112 may be subjected to surface modification to improve adhesion to the pressure sensitive adhesive layer 114. The surface modification may be realized by a physical or chemical process. The physical processes may include corona or plasma treatment; and the chemical processes may include in-line coating or primer treatment.

The base film 112 may have a thickness of about 30 to about 300 μm, in consideration of workability, UV transparency, and the like. Within this range, the base film 112 may help sufficiently relieve physical impact during the back-grinding process. Furthermore, a single roll of a final film product may have a suitable ratio of length to thickness to help reduce the frequency of replacement of the roll, thereby advantageously consuming less time and providing an advantage in terms of cost. In an implementation, the base film 112 may have a thickness of about 50 to 200 μm, thereby helping ensure that the base film 112 sufficiently contacts an irregular surface of a wafer on which bumps are formed.

(2) Pressure Sensitive Adhesive Layer

The adhesive film 110 for the semiconductor device may include the pressure sensitive adhesive layer 114 on one side of the base film 112. The pressure sensitive adhesive layer 114 may be a UV curable pressure sensitive adhesive layer, without being limited thereto.

Before UV irradiation, the pressure sensitive adhesive layer 114 may strongly support the (e.g., insulation) bonding layer 116 thereon and a wafer via strong tack, thereby reducing or preventing damage to the wafer caused by vibration or movement during the back-grinding process and reducing or preventing infiltration of chemical materials into interfaces between respective layers during CMP.

After UV irradiation, the pressure sensitive adhesive layer 114 may have increased cohesion and may shrink due to a crosslinking reaction. Thus, adhesion may be significantly reduced at an interface with the bonding layer 116, thereby facilitating separation of the pressure sensitive adhesive layer 114 and the base film 112 from the wafer attached to the bonding layer 116.

The pressure sensitive adhesive layer 114 may include a UV curable or non-UV curable composition. In a back-grinding tape, the non-UV curable composition may have relatively low adhesive strength, so that the pressure sensitive adhesive layer 114 of the non-UV curable composition may be easily peeled from an interface between the pressure sensitive adhesive layer 114 and the wafer by the reel-type adhesive film, even without UV irradiation.

However, for a wafer-level stack package (WSP) film, peeling should be achieved between the photocurable pressure sensitive adhesive layer 114 and the bonding layer 116, which is an organic interface. In this case, the pressure sensitive adhesive layer 114 of the non-UV curable composition may not be substantially peeled from the reel-type adhesive film. Thus, it may be desirable for the pressure sensitive adhesive layer 114 to be formed of a UV curable composition.

To be used for the WSP film, the photocurable pressure sensitive adhesive layer 114 may be formed of a composition in which a UV curable carbon-carbon double bond is introduced to a side chain of a binder, instead of a mixed composition. Such a composition (which may behave as a single molecule through introduction of a low-molecular weight compound having a carbon-carbon double bond to a side chain of an adhesive resin) may be referred to as an embedded type adhesive composition.

The embedded type adhesive binder may have a molecular weight of about 100,000 to about 1,000,000 and may be prepared by adding a low-molecular weight compound (having a C—C double bond) to a side chain of a copolymerized binder through a urethane reaction, in which a low-molecular weight compound having a terminal isocyanate group is used as the low-molecular weight compound having the C—C double bond.

The UV curable adhesive composition may be prepared by mixing the adhesive binder with a heat curing agent, a photoinitiator, and the like. For the adhesive composition, any suitable heat curing agent that can be cured through reaction with a functional group introduced to the side chain of the adhesive binder may be used.

For example, if the functional group provided to the side chain is a carboxyl group, an epoxy curing agent may be used; and if the functional group provided to the side chain is a hydroxyl group, an isocyanate curing agent may be used. In an implementation, melamine curing agents may be used, or a mixture of at least two of the epoxy, isocyanate, and melamine curing agents may be used.

For the adhesive composition, any suitable photoinitiator (e.g., ketone and acetophenone photoinitiators) that can generate a radical upon cleavage of a molecular bond thereof upon UV irradiation may be used. When the photoinitiator is added to the adhesive composition, the C—C double bond of the side chain of the adhesive binder may undergo a crosslinking reaction with the radical; and a glass transition temperature of the pressure sensitive adhesive layer may increase, thereby reducing tack of the pressure sensitive adhesive layer 114. When the pressure sensitive adhesive layer 114 loses tack, the pressure sensitive adhesive layer 114 may be separated from the bonding layer 116 with a relatively small amount of force.

The pressure sensitive adhesive layer 114 may be formed on the base film 112 by, e.g., direct coating or transfer coating. In the transfer coating, the pressure sensitive adhesive layer 114 may be deposited and dried on a release film and then transferred to the base film 112. The pressure sensitive adhesive layer 114 may be formed by any suitable coating method to form a layer, e.g., bar coating, gravure coating, comma coating, reverse-roll coating, applicator coating, spray coating, and the like.

(3) Bonding Layer

The adhesive film 110 for the semiconductor device may further include the bonding layer 116. For example, the bonding layer 116 may be omitted or may be stacked on the pressure sensitive adhesive layer 114 deposited on the base film 112.

The bonding layer 116 may be a layer in direct contact with a surface of the wafer. In the WSP film, it may be desirable for the bonding layer 116 to be stacked on the surface of the wafer (which may be highly irregular due to formation of bumps or the like thereon) without a void therebetween, and then to strongly bond both upper and lower sides of chips therein through die attachment.

For example, the bonding layer 116 may be used as an adhesive for finally bonding both upper and lower sides of chips. Thus, it may be desirable for the bonding layer 116 to have properties satisfying semiconductor packaging-level reliability and processibility for packaging. For example, it may be desirable that the irregular surface of the wafer be filled with the bonding layer 116 (without void occurrence) during a mounting process in order to to reduce or prevent chipping or cracking during a dicing process and deterioration in reliability due to swelling after the die-attachment process. The bonding layer 116 may be attached (at about 60° C.) to the surface of the wafer having bumps thereon, e.g., on which a circuit pattern is formed.

The bonding layer 116 is not particularly limited in composition, and may be formed of, e.g., a mixture of a high-molecular weight acrylic resin having film formability and an epoxy resin as a curing part. The bonding layer 116 may be a film-type adhesive. Thus, the acrylic resin (having excellent film formability) may be used as a thermoplastic resin in addition to the curing part exhibiting adhesion.

Further, any suitable epoxy resin that exhibits adhesion when cured may be used, and may include at least two functional groups in order to perform a curing reaction. In an implementation, at least one of a bisphenol-A epoxy resin, a phenol novolac epoxy resin, and a cresol novolac epoxy resin may be used.

As a curing agent to cure the epoxy resin, a curing accelerator may be used. Examples of the curing accelerator may include imidazole, amine, or phenolic curing accelerators, without being limited thereto.

As described above, the bonding layer 116 may be formed of the acrylic resin as a binder, the epoxy resin as a curing part, and the curing accelerator reactive therewith. In an implementation, the acrylic resin may be present in an amount of about 60 to about 150 parts by weight, based on 100 parts by weight of remaining components of the bonding layer 116 (except for the acrylic resin) and may have a glass transition temperature of about −30 to about 10° C.

Maintaining the glass transition temperature of the acrylic resin at about −30 to about 10° C. may help ensure that the acrylic resin has sufficient fluidity to fill the irregular surface having bumps with the acrylic resin at a mounting temperature of about 60° C. Further, when the binder not only has a glass transition temperature of about −30 to about 10° C. but is also present in an amount of about 60 parts by weight or more, based on 100 parts by weight of the remaining components (except for the acrylic resin), excellent film formability may be obtained and winding into a roll shape may be facilitated due to sufficient amounts of the binder. Maintaining the amount of the binder at about 150 parts by weight or less may help ensure that sufficient fluidity is obtained at 100° C. or more, thereby facilitating chip bonding without generation of bubbles.

In an implementation, inorganic particles, e.g., silica, may be added to help improve dimensional stability and heat resistance of the bonding layer 116. In another implementation, the bonding layer 116 (in contact with the surface of the wafer) may include at least one of various silane coupling agents to enhance adhesion to the wafer.

Any suitable coating method that can form a uniform bonding layer may be used to form the bonding layer 116. The bonding layer 116 may have a coating thickness of about 2 to about 30 μm. When the thickness is about 2 μm or more, the bonding layer may provide suitable adhesion between the upper and lower sides of the chips. When the thickness is about 30 μm or less, the bonding layer may be advantageous in view of a trend towards light, thin, and small semiconductor packages.

(4) Protective Film

The adhesive film 110 for the semiconductor device may include the base film 112, the pressure sensitive adhesive layer 114, the bonding layer 116, and the protective film 118 attached to the bonding layer 116.

Any suitable film that can protect the insulation bonding layer 116 from foreign materials or external impact may be used as the protective film 118. For example, a film used as a running film for coating the insulation bonding layer 116 may be used as the protective film 118. A semiconductor packaging process may be carried out after removing the outermost protective film 118. Thus, an easily releasable film may be used.

The protective film 118 may be, e.g., a polyethylene terephthalate film. In an implementation, the protective film 118 may be subjected to surface modification using a polydimethylsiloxane release agent, a fluorine release agent, or the like in order to provide releasing properties.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

Hereinafter, examples of processes of preparing pressure sensitive adhesive layer compositions and bonding layer compositions will be described.

Preparation Example 1 of a Pressure Sensitive Adhesive Layer Composition

2.4 kg of ethyl acetate and 1.2 kg of toluene, as organic solvents, were added to a 20 L 4-neck flask equipped with a reflux condenser, a thermometer, and a dropping funnel.

After heating the organic solvents to 60° C., a mixture solution was prepared using 510 g of methyl methacrylate, 540 g of a butyl acrylate monomer, 2.85 kg of 2-ethylhexyl acrylate, 1.8 kg of 2-hydroxyethyl methacrylate, 300 g of acrylic acid, and 39 g of benzoyl peroxide; and the mixture solution was dripped into to the flask using the dropping funnel at 60 to 70° C. for 3 hours. The mixture solution was added dropwise while stirring at 250 rpm.

After completion of the dripping, the resultant reactant was aged at the same temperature for 3 hours. Then, 600 g of methoxypropyl acetate and 2 g of azobisisobutyronitrile were added to the reactants and left for 4 hours, followed by measuring viscosity and solid content and terminating the reaction, thereby forming a polymerized product (acrylic adhesive binder). The polymerized product had a viscosity of 10,000 to 15,000 cps and a solid content of 40%.

Then, 450 g of glycidyl methacrylate was added to the prepared acrylic adhesive binder and reacted at 50° C. for 1 hour to prepare an embedded-type adhesive binder. 100 g of the prepared embedded-type adhesive binder was mixed with 2 g of an aromatic polyisocyanate heat curing agent (AK-75, Aekyung Chemical Co., Ltd.) and 1 g of a 1-hydroxycyclohexyl-phenyl ketone photoinitiator, IC-184 (Ciba-Geigy Co., Ltd.), thereby preparing a photocurable pressure sensitive adhesive layer composition.

Preparation Example 2 of a Bonding Layer Composition

30 kg of an acryl resin having a weight average molecular weight of 350,000 and a glass transition temperature of 12° C. (SG-80H, Nagase ChemTech Co., Ltd.), 4.5 kg of a cresol novolac epoxy resin having a molecular weight of 10,000 or less (YDCN-500-90P, Kukdo Chemical Co., Ltd.), 4.5 kg of a xyloc curing agent (MEH7800C, Meiwa Plastic Industries Co., Ltd.), 10 g of an imidazole curing accelerator (2P4MZ, Sikoku Chemical Co., Ltd.), 100 g of an amino silane coupling agent (KBM-573, Shin Estu Chemical Co., Ltd.), and 1.5 kg of rounded silica fillers (PLV-6XS, Tatsumori) were mixed and subjected to primary dispersion at 700 rpm for 2 hours, followed by milling, thereby preparing a bonding layer composition.

### EXAMPLES AND COMPARATIVE EXAMPLES

### Example 1

The photocurable pressure sensitive adhesive layer composition of Preparation

Example 1 was deposited on one side of a 38 μm PET release film (SRD-T38, Saehan Media Co., Ltd.) using a pilot coating system. Then, the product was stacked at 80° C. on a 100 μm polyolefin base film having a thermal contraction ratio of 0.06% at 5° C. and a coefficient of linear expansion (C.T.E) of 101 μm/m•° C. at 0 to 5° C. and aged in a dry room at 40° C. for 3 days, thereby preparing a photocurable pressure sensitive adhesive layer film.

The bonding layer composition of Preparation Example 2 was deposited to a thickness of 20 μm on one side of a 38 μm PET release film (SRD-T38, Saehan Media Co., Ltd.) using a pilot coating system and was then dried at 80° C. for 2 minutes. The product was then stacked on another 38 μm PET release film (SRD-T38, Saehan Media Co., Ltd.) at 80° C. and aged at room temperature of 25° C. for 3 days, thereby preparing a bonding layer film. After removing the release film from one side of the bonding layer film, the bonding layer film was stacked on the photocurable pressure sensitive adhesive layer film having the photocurable pressure sensitive adhesive layer (and having a wafer shape through precutting).

### Example 2

An adhesive film was prepared in the same manner as in Example 1 except that a 100 μm polyolefin film having a thermal contraction ratio of 0.02% at 5° C. and a coefficient of linear expansion (C.T.E) of 60 μm/m•° C. at 0 to 5° C. was used as a base film.

### Comparative Example 1

An adhesive film was prepared in the same manner as in Example 1 except that a 100 μm polyolefin film having a thermal contraction ratio of 0.3% at 5° C. and a coefficient of linear expansion (C.T.E) of 168 μm/m•° C. at 0 to 5° C. was used as a base film.

### Comparative Example 2

An adhesive film was prepared in the same manner as in Example 1 except that a 100 μm polyolefin film having a thermal contraction ratio of 0.15% at 5° C. and a coefficient of linear expansion (C.T.E) of 98 μm/m•° C. at 0 to 5° C. was used as a base film.

Table 1, below, illustrates winding shape stability of the adhesive films for semiconductor devices prepared in the Examples and Comparative Examples. As shown in Table 1, the adhesive films of Examples 1 and 2 (where a base film having a thermal contraction ratio of greater than 0 to about 0.1% after 120 hours at 5° C. and a coefficient of linear expansion of about 50 to about 150 μm/m•° C. at 0 to 5° C. was used) exhibited excellent winding shape stability. For example, when a base film having a thermal contraction ratio of greater than 0 to about 0.06% after 120 hours at 5° C. and a coefficient of linear expansion of about 60 to about 100 μm/m•° C. at 0 to 5° C. was used, the adhesive films exhibited excellent winding shape stability.

With excellent winding stability, the adhesive films may not tilt in one direction upon movement and operation, so that the wafer may be attached at a proper position when a pre-cut type is mounted; and a defect rate in a semiconductor assembly process may be reduced.

Further, among the adhesive films for the semiconductor device having a four-layer structure of a base film, a pressure sensitive adhesive layer, a bonding layer, and a protective film, the adhesive films having a thermal contraction ratio of greater than 0 to about 0.2% after 120 hours at 5° C. (Examples 1 and 2) exhibited excellent winding shape stability.

TABLE 1

| | | | | Compara- | Compara- |
|---|---|---|---|---|---|
| | | Exam- | Exam- | tive Ex- | tive Ex- |
| Kind | Unit | ple 1 | ple 2 | ample 1 | ample 2 |
| Base film | — | Poly- | Poly- | Poly- | Poly- |
| | | olefin | olefin | olefin | olefin |
| Thermal con- | % | 0.06 | 0.02 | 0.3 | 0.15 |
| traction ratio | | | | | |
| of base film | | | | | |
| (5° C.) | | | | | |
| C.T.E of base | μm/m · ° C. | 101 | 60 | 168 | 98 |
| film (5° C.) | | | | | |
| Thermal con- | % | 0.08 | 0.05 | 0.39 | 0.27 |
| traction ratio | | | | | |
| of four-layered | | | | | |
| adhesive film | | | | | |
| (5° C.) | | | | | |
| Winding shape | | ◯ | ◯ | X | X |
| stability | | | | | |

[Coefficient of Linear (Thermal) Expansion (C.T.E)]

Each base film having a thickness of 100 μm was cut into a 7 mm×14 mm (width×length) sample, followed by measuring a coefficient of linear expansion using a TMA Q7200 (TA Instrument) while elevating temperature at 5° C./min from −20 to 300° C.

[Thermal Contraction Ratio of Base Film]

Each base film was slit into 300-mm-wide specimens, and each specimen was wound with a winder tension of 5 N using a Winder R/M #002 (Master Co., Ltd) and stored in a low-temperature storage room at 5° C. for 120 hours, followed by measurement of contraction extent. The length (d) of each of four parts (as illustrated in FIG. 2) was measured three times; and a difference between average values before/after low-temperature storage was obtained, thereby calculating a thermal contraction ratio.

[Winding Shape Stability]

Each of the adhesive films in Examples 1 and 2 and Comparative Examples 1 and 2 was attached to a jig at 5° C., and a center part (core part) was pushed at 20 N for 20 seconds, followed by measurement of the length of tilting to the outside.

O: Tilting 20 mm or less

X: Tilting more than 20 mm

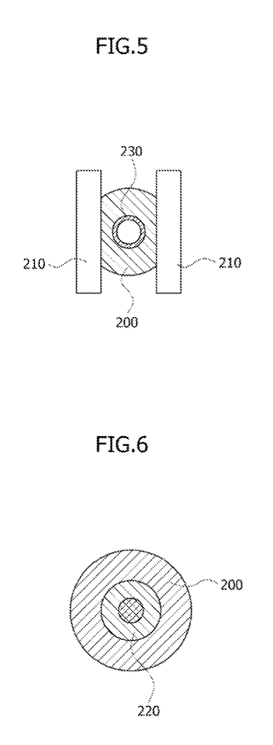

FIG. 4 illustrates a side sectional view of an adhesive film, showing evaluation of winding shape stability. FIG. 5 illustrates a side view of the adhesive film in a direction of Arrow A in FIG. 4. FIG. 6 illustrates a side view of the adhesive film in a direction of Arrow B in FIG. 4.

As shown in FIGS. 4 to 6, opposite ends in a thickness direction of an adhesive film 200 wound around a reel 230 were fixed using fixing jigs 210, and an intermediate jig 220 was installed at one end of the adhesive film 200 in a lengthwise direction. Then, after the intermediate jig 220 was pushed (in an X direction in FIG. 4), tilting length was measured.

[Thermal Contraction Ratio of Four-layer Die-Attach Film (DAF) Roll]

The adhesive film for the semiconductor device prepared in Example 1 was slit into 300-mm-wide specimens; and 200 m of the film was wound with a winder tension of 5 N using a Winder R/M #002 (Master Co., Ltd.) and stored in a low-temperature storage room at 5° C. for 120 hours, followed by measurement of contraction extent. The length (d) of each of four parts (as shown in FIG. 2) was measured three times; and a difference between average values before/after low-temperature storage was obtained, thereby calculating the thermal contraction ratio.

As described above, the base film and the adhesive film for the semiconductor device including the same according to the embodiments exhibit excellent winding shape stability after storage at low temperature for long time. Thus, occurrence of a tilting phenomenon may be reduced or prevented, thereby facilitating treatment and substantially reducing defects occurring in a subsequent semiconductor packaging process.

By way of summation and review, an adhesive film for semiconductor assembly may be used in conjunction with a dicing film. The dicing film may fix a semiconductor wafer during a dicing process of semiconductor chip manufacture. The dicing process is a process of sawing a semiconductor wafer into individual chips and may be followed by subsequent processes, e.g., expanding, picking-up, and mounting.

The dicing film may be formed by applying a UV-curable adhesive or a curable adhesive to an underlying film (having a polyolefin structure) and attaching a, e.g., PET, cover or release film thereto.

An adhesive film for semiconductor assembly may be used as follows. The bonding film may be attached to a semiconductor wafer; and a dicing film may then be deposited thereon (without the cover film), followed by dicing the wafer into individual chips. As a semiconductor assembly adhesive for dicing die bonding, a dicing film, (without the cover film), and a bonding film may be stacked into a single film; and a semiconductor wafer may be deposited thereon, followed by dicing the wafer into individual chips.

The embodiments provide an adhesive film for semiconductor devices that is capable of stably maintaining a winding shape after being stored at low temperature for long time, e.g., maintains stability in a winding form during long-term storage at low temperature.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An adhesive film for semiconductor devices, the adhesive film comprising a base film having a coefficient of linear expansion of about 50 to about 150 μm/m•° C. at 0 to 5° C.,
further comprising a pressure sensitive adhesive layer on one side of the base film,
further comprising a bonding layer and a protective film sequentially stacked on one side of the pressure sensitive adhesive layer,
wherein the base film has a thermal contraction ratio of greater than 0 to about 0.1% after 120 hours at 5° C.

2. The adhesive film as claimed in claim 1, wherein the base film includes at least one of a polyolefin, polyvinyl chloride, polyethylene terephthalate, polycarbonate, poly(methyl methacrylate), polyimide, polyethylene naphthalate, polyester sulfone, polystyrene, polyacrylate, and a thermoplastic elastomer.

3. The adhesive film as claimed in claim 1, wherein the pressure sensitive adhesive layer includes:
a pressure sensitive adhesive binder,
a heat curing agent, and
a photoinitiator.

4. The adhesive film as claimed in claim 3, wherein the pressure sensitive adhesive binder has a weight average molecular weight of about 100,000 to about 1,000,000.

5. The adhesive film as claimed in claim 1, wherein the adhesive film having a four-layer structure of a base film, a pressure sensitive adhesive layer, a bonding layer, and a protective film, the adhesive films has a thermal contraction ratio of greater than 0 to about 0.2% after 120 hours at 5° C.

6. The adhesive film as claimed in claim 1, wherein the bonding layer includes an acrylic resin and an epoxy resin.

7. The adhesive film as claimed in claim 6, wherein:
the acrylic resin has a glass transition temperature of about −30° C. to about 10° C., and
the epoxy resin includes one of a bisphenol-A resin, a phenol novolac resin, and a cresol novolac resin.
